(19) United States
(12) Patent Application Publication
(10) Pub. No.: US 2014/0102524 A1
(43) Pub. Date: Apr. 17, 2014

(54) NOVEL ELECTRON COLLECTORS FOR SILICON PHOTOVOLTAIC CELLS

(71) Applicant: Silevo, Inc., Fremont, CA (US)

(72) Inventors: Zhigang Xie, San Jose, CA (US); Jiunn Benjamin Heng, San Jose, CA (US); Wei Wang, San Jose, CA (US); Jianming Fu, Palo Alto, CA (US); Zheng Xu, Pleasanton, CA (US)

(73) Assignee: Silevo, Inc., Fremont, CA (US)

(21) Appl. No.: 14/054,688

(22) Filed: Oct. 15, 2013

Related U.S. Application Data
(60) Provisional application No. 61/713,871, filed on Oct. 15, 2012.

(51) Int. Cl. H01L 31/0352; H01L 31/18

(52) U.S. Cl. CPC H01L 31/035209; H01L 31/1884
USPC 136/255; 438/87

(57) ABSTRACT

One embodiment of the present invention provides a solar cell. The solar cell includes a base layer comprising crystalline Si (c-Si), an electron collector situated on a first side of the base layer, and a hole collector situated on a second side of the base layer, which is opposite the first side. The electron collector includes a quantum-tunneling-barrier (QTB) layer situated adjacent to the base layer and a transparent conducting oxide (TCO) layer situated adjacent to the QTB layer. The TCO layer has a work function of less than 4.2 eV.

### RELATED APPLICATION

This application claims the benefit of U.S. Provisional Application No. 61/713,871, Attorney Docket Number SSP12-1005PSP, entitled “Low Absorption Emitter for Crystalline Silicon Solar Cells with Low-Work-Function-TCO and Tunneling Oxide,” by inventors Zhigang Xie, Wei Wang, Jiunn Benjamin Heng, Jianming Fu, and Zheng Xu, filed 15 Oct. 2012.

### BACKGROUND

1. Field

This disclosure is generally related to solar cells. More specifically, this disclosure is related to a novel electron collector in a crystalline-Si (c-Si) based solar cell. The electron collector is formed by depositing a layer of low work function TCO and a layer of tunneling oxide on top of the c-Si base layer.

2. Related Art

The negative environmental impact caused by the use of fossil fuels and their rising cost have resulted in a dire need for cleaner, cheaper alternative energy sources. Among different forms of alternative energy sources, solar power has been favored for its cleanness and wide availability.

A solar cell converts light into electricity using the photoelectric effect. There are many solar cell structures and a typical solar cell contains a p-n junction that includes a p-type doped layer and an n-type doped layer. In addition, there are other types of solar cells that are not based on p-n junctions. For example, a solar cell can be based on a metal-insulator-semiconductor (MIS) structure that includes an ultra-thin dielectric or insulating interfacial tunneling layer situated between a metal or a highly conductive layer and a doped semiconductor layer.

In a p-n junction based solar cell, the absorbed light generates carriers. These carriers diffuse into the p-n junction and are separated by the built-in electric field, thus producing an electrical current across the device and external circuitry. An important metric in determining a solar cell's quality is its energy-conversion efficiency, which is defined as the ratio between power converted (from absorbed light to electrical energy) and power collected when the solar cell is connected to an electrical circuit.

To increase the conversion efficiency, a solar cell structure should allow the photon-generated carriers to effectively transport to the electrode. To do so, high-quality carrier collectors for both types of carriers (electrons and holes) are needed. A typical p-n junction based solar cell includes a lightly n- or p-type doped base and a heavily doped emitter with an opposite doping type. For solar cells with an n-type doped emitter, electrons are collected by the n-type emitter, and the holes flow to the opposite side. The n-type doped emitter is also called an electron collector. To prevent minority carrier recombination at the surface of the opposite side, a back surface field (BSF) layer (which is often a heavily doped layer having the same doping type as the base) can be formed at the surface of the opposite side. If the BSF layer is p-type doped, it collects holes. Similarly, for solar cells with a p-type doped emitter, holes are collected by the p-type emitter, and electrons flow to the opposite side to be collected by the n-type BSF layer.

Surface passivation is important for solar cell performance because it directly impacts the open circuit voltage (V_{oc}). Note that a good V_{oc} implies a good temperature coefficient, which enables a better solar cell performance at higher temperatures. One attempt to passivate the surface of the solar cell is to cover the surface of the Si absorber with materials having a wider bandgap, such as amorphous-Si (a-Si), or a thin layer of insulating material (such as silicon oxide or nitride). However, such passivation layers often impede current flows unintentionally.

### SUMMARY

One embodiment of the present invention provides a solar cell. The solar cell includes a base layer comprising crystalline Si (c-Si), an electron collector situated on a first side of the base layer, and a hole collector situated on a second side of the base layer, which is opposite the first side. The electron collector includes a quantum-tunneling-barrier (QTB) layer situated adjacent to the base layer and a transparent conducting oxide (TCO) layer situated adjacent to the QTB layer. The TCO layer has a work function of less than 4.2 eV.

In a variation on this embodiment, the base layer includes at least one of: a monocrystalline silicon wafer and an epitaxially grown crystalline-Si (c-Si) thin film.

In a variation on this embodiment, the QTB layer comprises at least one of: silicon oxide (SiOₓ), hydrogenated SiOₓ, silicon nitride (SiNₓ), hydrogenated SiNₓ, aluminum oxide (AlOₓ), aluminum nitride (AlNₓ), silicon oxynitride (SiON), hydrogenated SiON, amorphous Si (a-Si), hydrogenated a-Si, carbon doped Si, and SiC.

In a variation on this embodiment, the QTB layer has a thickness between 1 and 50 angstroms.

In a variation on this embodiment, the QTB layer comprises one of: SiOₓ and hydrogenated SiOₓ. The QTB layer is formed using at least one of the following techniques: running hot deionized water over the base layer, ozone oxygen oxidation, atomic oxygen oxidation, thermal oxidation, wet or steam oxidation, atomic layer deposition, low-pressure radical oxidation, and plasma-enhanced chemical-vapor deposition (PECVD).

In a variation on this embodiment, the TCO layer includes one or more of: tungsten doped indium oxide (IWO), Sn doped indium oxide (ITO), fluorine doped tin oxide (F:SnO₂), zinc doped indium oxide (IZO), zinc and tungsten doped indium oxide (IZWO), and aluminum doped zinc oxide (AZO).

In a variation on this embodiment, the TCO layer is formed using a low damage deposition technique comprising one of: radio frequency (RF) sputtering, thermal evaporation, molecular beam epitaxy (MBE), metalorganic chemical-vapor deposition (MOCVD), atomic layer deposition (ALD), and ion plating deposition (IPD).

In a variation on this embodiment, the electron collector is situated on a front surface of the solar cell, facing incident light. If the base layer is lightly doped with p-type dopants, then the electron collector acts as a front-side emitter. If the base layer is lightly doped with n-type dopants, then the electron collector acts as a front surface field (FSF) layer.

In a further variation, the hole collector is situated on a back surface of the solar cell, facing away from the incident light. If the base layer is lightly doped with p-type dopants, then the hole collector acts as a back surface field (BSF) layer. If the base layer is lightly doped with n-type dopants, then the hole collector acts as a back-side emitter.

In a further variation, the hole collector comprises one or more of: a QTB layer, amorphous-Si (a-Si), hydrogenated a-Si, and microcrystalline Si.

In a further variation, the hole collector is graded doped and has a doping concentration ranging between 1×10¹²/cm³ and 5×10²⁰/cm³.

In a variation on this embodiment, the electron collector is situated on a back surface of the solar cell, facing away from incident light. If the base layer is lightly doped with p-type dopants, then the electron collector acts as a back-side emitter. If the base layer is lightly doped with n-type dopants, then the electron collector acts as a back surface field (BSF) layer.

In a further variation, the hole collector is situated on a front surface of the solar cell, facing the incident light. If the base layer is lightly doped with p-type dopants, then the hole collector acts as a front surface field (FSF) layer. If the base layer is lightly doped with n-type dopants, then the hole collector acts as a front-side emitter.

In a variation on this embodiment, the base layer has an n-type or a p-type doping concentration ranging between 5×10¹⁴/cm³ and 1×10¹⁶/cm³.

In a variation on this embodiment, the base layer includes a shallow doping layer heavily doped with n-type dopants. The shallow doping layer has a peak doping concentration of at least 1×10¹⁹/cm³ and a junction depth of less than 100 nm.

### BRIEF DESCRIPTION OF THE FIGURES

FIG. 1A presents a diagram illustrating the band diagram at the interface between crystalline-Si and a TCO material that has a work function that is slightly below the Si conduction band edge.

FIG. 1B presents a diagram illustrating the band diagram at the interface between crystalline-Si and a TCO material that has a work function considerably smaller than the Si conduction band edge.

FIG. 1C presents a diagram illustrating the band diagram at the interface between crystalline-Si and a TCO material that has a work function slightly larger than the Si conduction band edge.

FIG. 2 presents a diagram illustrating an exemplary solar cell with the TCO/QTB electron collector, in accordance with an embodiment of the present invention.

FIG. 3 presents a diagram illustrating an exemplary solar cell with the TCO/QTB electron collector, in accordance with an embodiment of the present invention.

FIG. 4 presents a diagram illustrating the process of fabricating a solar cell with a novel electron-collecting emitter, in accordance with an embodiment of the present invention.

FIG. 5 presents a diagram illustrating the process of fabricating a solar cell with a novel electron-collecting BSF layer, in accordance with an embodiment of the present invention.

FIG. 6A presents a diagram illustrating an exemplary solar cell with the TCO/QTB electron collector, in accordance with an embodiment of the present invention.

FIG. 6B presents a diagram illustrating an exemplary doping profile of the shallow doping.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Embodiments of the present invention provide a crystalline-Si (c-Si) based solar cell that includes a novel, transparent electron collector. The novel electron collector includes a layer of transparent conducting oxide (TCO) material that has a work function that is less than 4.2 eV and a quantum tunneling barrier (QTB) layer. The novel, transparent electron collector can be situated at either the front or the back side of the solar cell with the QTB layer in direct contact with the c-Si base layer, and can act as either an emitter or a back surface field (BSF) layer.

### The TCO/QTB-Based Electron Collector

Excellent surface passivation is a key to achieving high-efficiency solar cells. In addition, it is important to ensure that such excellent surface passivation does not impede current flow. In conventional Si-based solar cells, lightly doped or intrinsic amorphous Si (a-Si) or hydrogenated a-Si are often used to passivate the surface of c-Si substrates. The passivation effect is due to the reduction of the interface dangling bonds and the positive valence band offset between a-Si and c-Si. However, the presence of the a-Si passivation layer means that, to reach to the p-type emitter, holes need to tunnel through this band offset barrier and also need to hop through the lightly doped a-Si region. This can lead to much higher current loss due to internal recombination and the dramatically lower drift velocity through the interface. Hence, heavily doped emitter layers or BSF layers would be needed at both sides of the solar cell. However, emitter absorption can also limit the performance of the conventional heterojunction solar cells, because light absorbed by the emitter layer cannot contribute to the photocurrent. A typical heterojunction solar cell may lose up to 5% of light due to the emitter absorption. Usually there is a conflict between reducing absorption loss and surface passivation loss.

For solar cells fabricated using diffusion-based technologies, the heavily doped region on the front side of the solar cell may cause blue-blindness and current loss unless a selective-emitter technology is used. However, such technologies often require fine patterning and localized laser dopant activation, which may add to fabrication complexity and cost.

Although surface passivation using a-Si or a-Si:H can improve the solar cell performance by reducing surface recombination, such passivation is not ideal and the resulting open circuit voltage can be limited (often less than 640 mV). Thermal oxide used as a tunneling barrier can also provide low dangling bond interface, and can provide better surface passivation to generate a higher open circuit voltage (can be as high as 730 mV). However, this tunneling mechanism can limit the final short circuit current. More specifically, the intra-band tunneling between two non-degenerated semiconductor materials is not strong enough to sustain the high flow of photocurrent.

In addition to the heavily doped p-type emitter made of wider bandgap semiconductor materials, metal-insulator-semiconductor (MIS) structures have been used as n-type emitters in solar cell applications. Al is often used as the metal layer due to its low work function (at around 4.0 eV). However, because Al or other metals are not transparent and do not work well in spreading and collecting current, the MIS emitter is often located at the back side of the solar cell. Moreover, deposition of metals can often result in increased Dᵢₜ on the surface of the semiconductor.

To overcome the aforementioned shortcomings of the light-absorbing emitters of conventional Si-based heterojunction solar cells, embodiments of the present invention provide solar cells that include an electron collector that is transparent to visible light. The transparent electron collector interfaces directly with the c-Si base, and can function as either an emitter or a BSF layer, depending on the doping type of the base layer. In some embodiments, the transparent electron collector includes a TCO layer and a thin quantum tunneling barrier (QTB) layer.

In embodiments of the present invention, instead of having an emitter made of a wider bandgap material (such as a-Si), the TCO/QTB structure can serve as a p-type emitter by directly interfacing with the c-Si base layer. More specifically, the TCO layer, which is heavily doped, can act as a metal layer, and the QTB layer can function as a passivation layer and tunneling barrier. For electron collection purposes, the work function of the TCO should match the conduction band edge of the c-Si, which is roughly 4.05 eV.

TCO material has been widely used to coat the front side of heterojunction solar cells in order to facilitate the spread of the photogenerated current and to provide anti-reflection coating (ARC). Typical TCO materials have a wider bandgap, thus being transparent to visible light. The heavily doped TCO material may incur absorption loss at the near IR regime. In general, a good TCO film may introduce 2-2.5% optical loss, all in the near IR regime. Compared with the light loss caused by conventional p-type emitters, optical loss induced by the TCO layer is much less.

Note that most TCO materials are heavily doped to an extent (with a doping concentration of at least 1×10¹⁹/cm³, sometimes higher than 2×10²⁰/cm³) that they have degenerated carrier distribution. Moreover, the improved low-damage deposition techniques have made it possible to deposit a TCO film with an interface defect density (Dᵢₜ) less than 1 e¹¹/cm². The degenerated carrier distribution in the TCO film and the low Dᵢₜ make it possible to have a strong tunneling effect when the TCO/QTB structure is in contact with a lightly doped c-Si base. The tunneling process depends on the available carrier concentration at the starting side (the c-Si side) and the density of states at the receiving side (the TCO side), according to the Wentzel-Kramers-Brillouin (WKB) approximation. Based on the difference between the TCO work function and the c-Si conduction band edge, there are three different situations when strong tunneling is present.

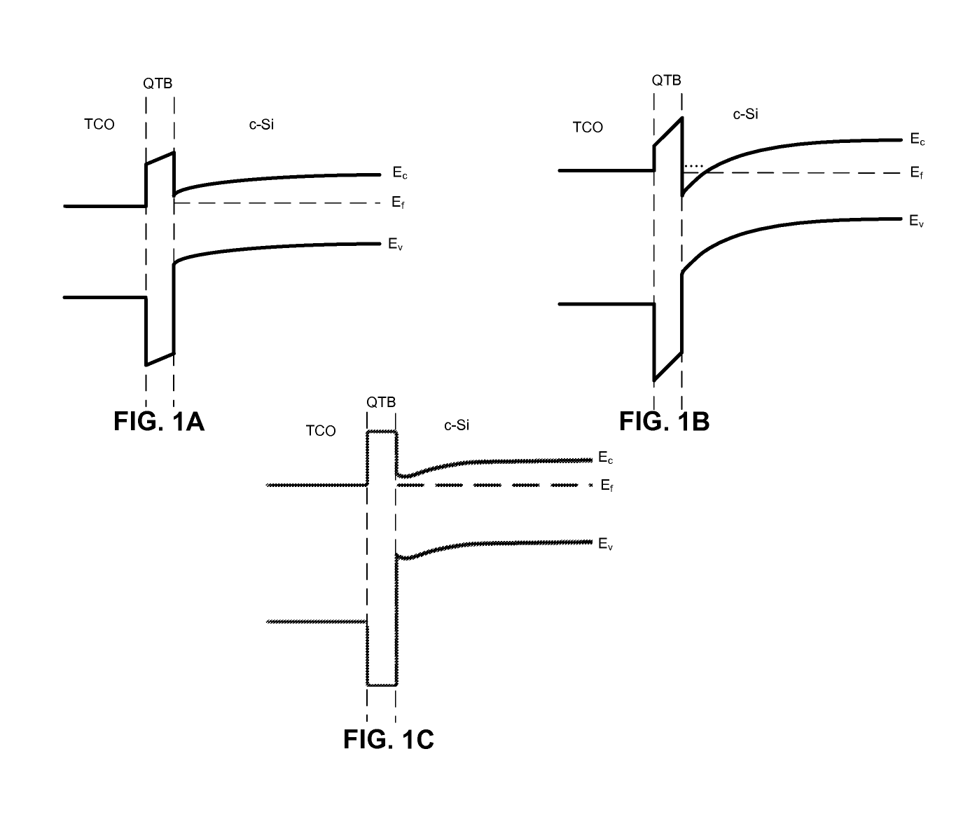

FIG. 1A presents a diagram illustrating the band diagram at the interface between crystalline-Si and a TCO material that has a work function that is slightly below the Si conduction band edge. In FIG. 1A, the work function of the TCO material is slightly below (the difference is within 0.1 eV) the c-Si conduction band edge. Due to the tunneling effect, electrons can be transferred from the c-Si side to the TCO side. Depending on the doping type of the lightly doped c-Si, there might be electron accumulation (if the c-Si is n-type doped) or carrier inversion (if the c-Si is p-type doped) at the interface, and the highest electron concentration can be close to the TCO doping (around 1×10²⁰/cm³). Note that, as shown in FIG. 1A, there is band bending at the QTB-Si interface, pushing the Fermi level closer to the E_{c} of the Si. Because the band offset between the Si and the TCO is very small, and considering the thermal broadening, the tunneling effect can be quite strong.

FIG. 1B presents a diagram illustrating the band diagram at the interface between crystalline-Si and a TCO material that has a work function considerably smaller than the Si conduction band edge. In FIG. 1B, the work function of the TCO material is considerably smaller than the Si conduction band edge, which is 4.05 eV. At the QTB/Si interface, the slope for the band bending is so big that the triangular shape barrier is just a few nanometers thick and quantum wells for electrons are forming. As a result, the lowest energy level for the heavily degenerated electrons on the Si side is not at the conduction band edge, but is the first confinement energy level, which can be within 0.1 eV gap to the conduction band edge (as shown by the dots in FIG. 1B). Therefore, there is no obvious energy level offset for the intra-band tunneling of the electrons. Holes, on the other hand, will be repelled by the barrier. There will be no tunneling of the holes because the receiving side is within the forbidden band.

FIG. 1C presents a diagram illustrating the band diagram at the interface between crystalline-Si and a TCO material that has a work function slightly larger than the Si conduction band edge. In FIG. 1C, the work function of the TCO material is larger than the E_{c} of c-Si by about 0.05-0.15 eV. In such a situation, there will be no issue of band alignment. Electrons with energy levels starting from the conduction band edge E_{c} will enter from the c-Si side to the unfilled conduction band of the TCO. But there will be fewer electrons transferring from the TCO side to the c-Si side. As a result, the electron concentration at the QTB/Si interface will be less than 1×10¹⁸/cm³. Hence, there is not enough band bending at the interface and the passivation is compromised. To improve the passivation, one can apply shallow n-type doping at the surface of the c-Si substrate. Note that, in order to prevent the blue-blindness, the shallow doping should have a peak concentration of at least 1×10¹⁹/cm³ and a depth of less than 100 nm. Also note that, in this case, the surface recombination velocity is not sensitive to the doping depth, but extremely sensitive to the peak doping concentration.

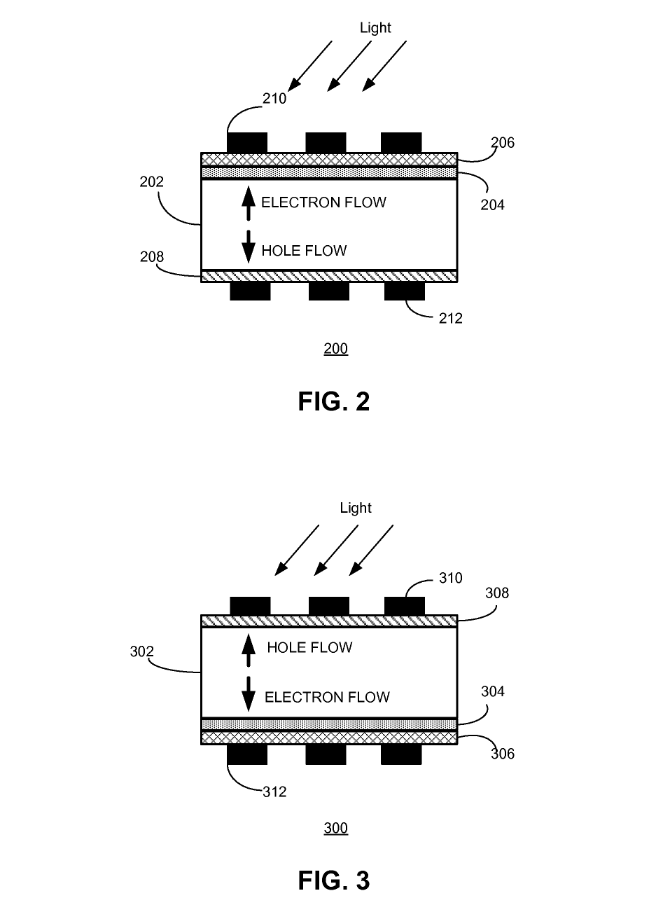

FIG. 2 presents a diagram illustrating an exemplary solar cell with the TCO/QTB electron collector, in accordance with an embodiment of the present invention. Solar cell 200 includes a substrate 202, a QTB layer 204, a TCO layer 206, a back surface field (BSF) layer 208, a front-side electrode 210, and a back-side electrode 212.

Substrate 202 includes a layer of c-Si that is epitaxially grown or a c-Si wafer cut from an ingot obtained via the Czochralski (CZ) or floating zone (FZ) process and is lightly doped with either n-type dopants or p-type dopants. In one embodiment, substrate 202 is p-type doped. The thickness of substrate 202 can be between 80 and 300 μm. In some embodiments, the thickness of substrate 202 is between 120 and 180 μm. The doping concentration of substrate 202 can be between 5×10¹⁴/cm³ and 1×10¹⁶/cm³. In one embodiment, the doping concentration of substrate 202 is less than 5×10¹⁵/cm³. In a further embodiment, substrate 202 is graded doped with the doping concentration at the Si/QTB interface being larger than 1×10¹⁹/cm³.

QTB layer 204 directly contacts substrate 202, and can include one or more of: a dielectric thin film and a layer of wide bandgap semiconductor material with low or intrinsic doping. Exemplary materials used for the dielectric thin film include, but are not limited to: silicon oxide (SiOₓ), hydrogenated SiOₓ, silicon nitride (SiNₓ), hydrogenated SiNₓ, silicon oxynitride (SiON), hydrogenated SiON, aluminum oxide (AlOₓ), and aluminum nitride (AlNₓ). Examples of the wide bandgap materials include, but are not limited to: amorphous Si (a-Si), hydrogenated a-Si, carbon doped a-Si, and silicon carbide (SiC). In one embodiment, QTB layer 204 includes either SiOₓ, such as SiO; or hydrogenated SiOₓ. The SiOₓ or hydrogenated SiOₓ layer can be formed using various oxidation techniques, such as running hot deionized water over the substrate, ozone oxygen oxidation, atomic oxygen oxidation, thermal oxidation, steam or wet oxidation, atomic layer deposition, and plasma-enhanced chemical-vapor deposition (PECVD). The thickness of QTB layer 204 can be between 5 and 50 angstroms. In one embodiment, QTB layer 204 includes a SiOₓ layer having a thickness between 8 and 15 Å.

TCO layer 206 includes a layer of low work function TCO material. In one embodiment, the low work function TCO material has a work function of less than 4.2 eV. Note that, although most common TCO materials have work functions within the range between 4.5 and 4.6 eV, obtaining TCO materials with lower work functions is also possible. For example, aluminum doped zinc oxide (AZO) can be a good candidate with a special mixture of crystal phase/orientations. Other examples of low work function TCO materials include, but are not limited to: tungsten doped indium oxide (IWO), Sn doped indium oxide (ITO), fluorine doped tin oxide (F:SnO₂), zinc doped indium oxide (IZO), zinc and tungsten doped indium oxide (IZWO), and their combinations. Note that the work function of most TCO materials can be tuned by adjusting the carrier concentration and doping. In addition, one can control the TCO work function by controlling the crystalline orientation and surface condition. To ensure sufficiently low Dᵢₜ, in one embodiment, TCO layer 206 is deposited on QTB layer 204 using a low-damage deposition method. Examples of low-damage deposition methods include, but are not limited to: radio frequency (RF) sputtering; thermal evaporation; epitaxial growth, such as molecular beam epitaxy (MBE) and metalorganic chemical-vapor deposition (MOCVD); atomic layer deposition (ALD); and ion plating deposition (IPD). In one embodiment, the Dᵢₜ at the TCO/QTB interface is less than 1×10¹¹/cm², which ensures good surface passivation. TCO layer 206 is often heavily doped (with metal ions) with a doping concentration of at least 1×10¹⁹/cm³. In one embodiment, the doping concentration of TCO layer 206 is greater than 2×10²⁰/cm³. The thickness of TCO layer 206 can be controlled to meet the anti-reflection requirement. In one embodiment, TCO layer 206 also acts as an anti-reflection (AR) coating, having a thickness of around 100 nm.

Note that TCO layer 206 and QTB layer 204 together form an n-type emitter, and collect electron current, as shown in FIG. 2 by the upwardly pointing arrow. Compared with the conventional n-type emitters made of wide bandgap materials, such as a-Si, this novel emitter/electron collector reduces emitter absorption because both TCO layer 206 and QTB layer 204 are transparent to visible light.

BSF layer 208 can include a Si layer that is heavily doped with p-type dopant, and is responsible for collecting hole current, as shown in FIG. 2 by the downwardly pointing arrow. In one embodiment, there can be an additional QTB layer situated between BSF layer 208 and substrate 202. Front-side electrode 210 and back-side electrode 212 are responsible for collecting the corresponding current. In one embodiment, front-side electrode 210 and back-side electrode 212 include an electroplated or screen-printed metal grid.

In the example shown in FIG. 2, layer 208 is heavily doped with p-type dopants, and substrate 202 can be doped with either n- or p-type dopants. If substrate 202 is lightly doped with p-type dopants, then the TCO/QTB structure will act as a front-side emitter and layer 208 will act as a BSF layer. On the other hand, if substrate 202 is lightly doped with n-type dopants, then the TCO/QTB structure will act as a front surface field (FSF) layer and layer 208 will act as a back-side emitter. In both situations, the TCO/QTB structure collects electron current and the heavily p-doped layer 208 collects hole current.

Note that the TCO/QTB structure collects electron current when placed in direct contact with the lightly doped c-Si substrate. Hence, in addition to functioning as an n-type emitter and being placed at the light-facing side of a solar cell, it is also possible to place this structure at the backside of the solar cell. In one embodiment, the solar cell includes a front p-type emitter that collects hole current and a back TCO/QTB structure acting as a BSF layer to collect electron current. Note that because the TCO/QTB structure is transparent to visible light, the solar cell can be bifacial, meaning that light shining on both sides of the solar cell can be absorbed to generate photo current.

FIG. 3 presents a diagram illustrating an exemplary solar cell with the TCO/QTB electron collector, in accordance with an embodiment of the present invention. Solar cell 300 includes a substrate 302, a QTB layer 304, a TCO layer 306, a front-side emitter layer 308, a front-side electrode 310, and a back-side electrode 312.

Substrate 302 can be similar to substrate 202 shown in FIG. 2. More specifically, substrate 302 can include lightly doped c-Si, with a doping concentration of less than 1×10¹⁶/cm³. The thickness of substrate 302 can be between 80 and 300 μm. In some embodiments, the thickness of substrate 302 is between 120 and 180 μm. Like substrate 202, substrate 302 can be either n-type doped or p-type doped. In one embodiment, substrate 302 is lightly doped with p-type dopants.

QTB layer 304 is situated directly underneath substrate 302. Materials and processes used to form QTB layer 304 can be similar to those used to form QTB layer 204. In addition, the thickness of QTB layer 304 is similar to that of QTB layer 204, which can be between 5 and 50 angstroms.

Like TCO layer 206, TCO layer 306 includes a layer of low work function TCO material, such as AZO, IWO, ITO, F:SnO₂, IZO, IZWO, and their combinations. The process used to form TCO layer 306 can be similar to the one used to form TCO layer 206. If solar cell 300 is bifacial, TCO layer 306 can also be used as an AR coating.

Because the TCO/QTB structure shown in FIG. 3 is used to collect electron current at the backside of solar cell 300, front-side emitter 308 needs to be able to collect hole current. In one embodiment, front-side emitter 308 is a p-type emitter. Front-side emitter 308 not only collects hole current but can also passivate the surface. Materials used to form front-side emitter 308 can include, but are not limited to: a-Si, a multi-crystalline semiconductor material, and a wide bandgap semiconductor material. Front-side emitter 308 can be graded doped, with a doping range from 1×10¹²/cm³ to 5×10²⁰/cm³. The region that is close to the interface between emitter 308 and substrate 302 has a lower doping concentration. In some embodiments, front-side emitter 308 may include one of: a metal-insulator-semiconductor (MIS) structure, or a TCO-insulator-semiconductor structure. Note that in order to collect holes, the TCO used here needs to have a high (larger than 5.0 eV) work function. In one embodiment, it is also possible to have an additional QTB layer situated between front-side emitter 308 and substrate 302.

Front-side electrode 310 and back-side electrode 312 are responsible for collecting the corresponding current. In one embodiment, front-side electrode 310 and back-side electrode 312 include an electroplated or screen-printed metal grid.

In the example shown in FIG. 3, layer 308 is heavily doped with p-type dopants, and substrate 302 can be doped with either n- or p-type dopants. If substrate 302 is lightly doped with n-type dopants, then the TCO/QTB structure will act as a BSF layer and layer 308 will act as a front-side emitter. On the other hand, if substrate 302 is lightly doped with p-type dopants, then the TCO/QTB structure will act as a back-side emitter and layer 308 will act as an FSF layer. In both situations, the TCO/QTB structure collects electron current and the heavily p-doped layer 308 collects hole current.

Note that, although in FIGS. 2 and 3, the light is coming from the top side of the solar cells (as shown by the arrows), in practice, because the TCO/QTB structure is transparent, it is possible to have light coming from both sides of the solar cells.

### Fabrication Method

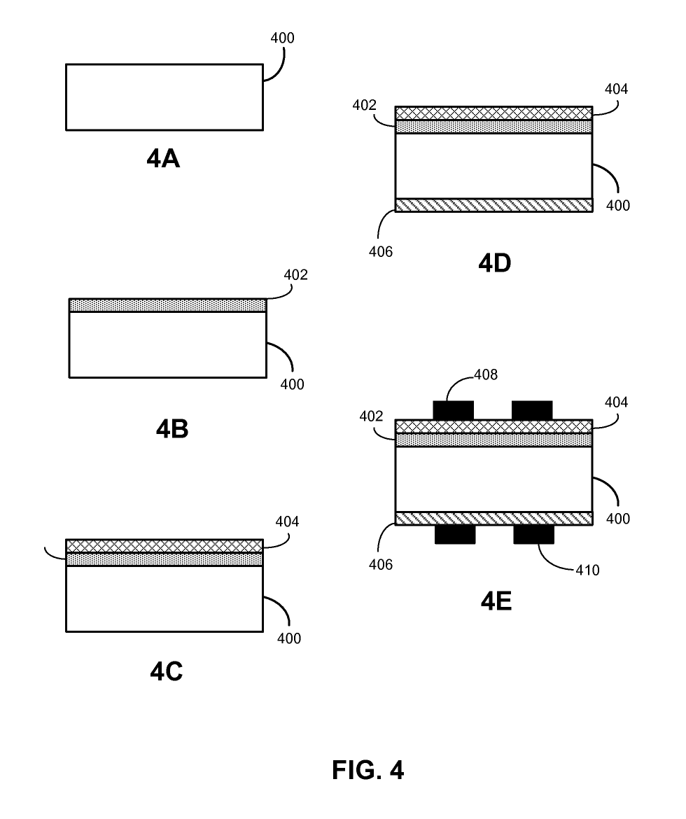

Either n- or p-type doped high-quality solar-grade silicon (SG-Si) wafers can be used to build the solar cell with the novel electron collector. In one embodiment, a p-type doped SG-Si wafer is selected to fabricate a solar cell with the TCO/QTB structure acting as an electron-collecting emitter. FIG. 4 presents a diagram illustrating the process of fabricating a solar cell with a novel electron-collecting emitter, in accordance with an embodiment of the present invention.

In operation 4A, an SG-Si substrate 400 is prepared. The resistivity of the SG-Si substrate is typically in, but not limited to, the range between 0.5 ohm-cm and 10 ohm-cm. SG-Si substrate can include a monocrystalline Si wafer that is cut from an ingot obtained via the CZ/FZ process. The preparation operation includes typical saw damage etching that removes approximately 10 μm of silicon. In one embodiment, surface texturing can also be performed. Afterwards, the SG-Si substrate goes through extensive surface cleaning. In addition, SG-Si substrate can also come from an epitaxial process (such as MBE or MOCVD) where a c-Si epitaxial film is grown on and then removed from a growth substrate. In one embodiment, SG-Si substrate is lightly doped with p-type dopants with a doping concentration that ranges between 5×10¹⁴/cm³ and 1×10¹⁶/cm³.

In operation 4B, a thin layer of high-quality (with D, less than 1×10¹¹/cm²) dielectric or wide bandgap semiconductor material is deposited on the front surface of SG-Si substrate 400 to form front-side passivation/tunneling layer 402. In one embodiment, both the front and back surfaces of SG-Si substrate 400 are deposited with a thin layer of dielectric or wide bandgap semiconductor material. Various types of dielectric materials can be used to form the passivation/tunneling layers, including, but not limited to: silicon oxide (SiOₓ), hydrogenated SiOₓ, silicon nitride (SiNₓ), hydrogenated SiNₓ, silicon oxynitride (SiON), hydrogenated SiON, aluminum oxide (AlOₓ), and aluminum nitride (AlNₓ). If front-side passivation/tunneling layer 402 includes SiOₓ or hydrogenated SiOₓ, various deposition techniques can be used to deposit such oxide layers, including, but not limited to: thermal oxidation, atomic layer deposition, wet or steam oxidation, low-pressure radical oxidation, plasma-enhanced chemical-vapor deposition (PECVD), etc. The thickness of the tunneling/passivation layer can be between 5 and 50 angstroms, preferably between 8 and 15 angstroms. Note that a well-controlled thickness of the tunneling/passivation layer ensures good tunneling and passivation effects. In addition to dielectric material, a variety of wide bandgap semiconductor materials, such as a-Si, hydrogenated a-Si, carbon doped a-Si, and SiC, can also be used to form the tunneling/passivation layer.

In operation 4C, a layer of low work function TCO material is deposited on top of front-side passivation/tunneling layer 402 using a low damage deposition technique to form a TCO layer 404. In one embodiment, the work function of TCO layer 404 is less than the c-Si conduction band edge, or 4.05 eV. Examples of low work function TCO materials include, but are not limited to: AZO, IWO, ITO, F:SnO₂, IZO, IZWO, and their combinations. Examples of the low-damage deposition technique include, but are not limited to: radio frequency (RF) sputtering; thermal evaporation; epitaxial growth, such as molecular beam epitaxy (MBE) and metalorganic chemical-vapor deposition (MOCVD); atomic layer deposition (ALD); and ion plating deposition (IPD). In one embodiment, the Dᵢₜ at the TCO/QTB interface is controlled to be less than 1×10¹¹/cm², which ensures good surface passivation. The thickness of TCO layer 404 can be determined based on the anti-reflection requirement.

The combination of low work function TCO layer 404 and passivation/tunneling layer 402 functions as an electron-collecting emitter when directly interfaced with SG-Si substrate 400. Such a structure eliminates the need for an additional emitter that can collect electrons and is made of wide bandgap materials, which may absorb a small portion of incoming light. On the contrary, this new electron-collecting emitter is transparent to visible light, thus significantly increasing solar cell efficiency. In addition, the elimination of the wide bandgap emitter simplifies the fabrication process, as the deposition of a TCO layer has been part of the standard fabrication process of the conventional solar cells.

In operation 4D, a layer of a-Si with graded doping is deposited on the back surface of SG-Si substrate 400 to form back surface field (BSF) layer 406. In one embodiment, BSF layer 406 is p-type doped using boron as dopant. The thickness of BSF layer 406 can be between 3 and 30 nm. BSF layer 406 collects the hole current and improves the back-side passivation. For graded doped BSF layer 406, the region within BSF layer 406 that is adjacent to SG-Si substrate 400 has a lower doping concentration, and the region that is away from SG-Si substrate 400 has a higher doping concentration. The lower doping concentration ensures minimum defect density at the interface between SG-Si substrate 400 and BSF layer 406, and the higher concentration on the other side ensures good ohmic-contact with the subsequently formed back-side electrode. In one embodiment, the doping concentration of BSF layer 406 varies from 1×10¹²/cm³ to 5×10²⁰/cm³. In addition to a-Si, it is also possible to use other materials, such as hydrogenated a-Si, microcrystalline Si, or a semiconductor material with a wide bandgap, to form BSF layer 406. Using microcrystalline Si material for BSF layer 406 can ensure lower series resistance and better ohmic contact.

In operation 4E, front-side electrode 408 and back-side electrode 410 are formed on the surfaces of TCO layer 404 and BSF layer 406, respectively. In some embodiments, front-side electrode 408 and/or back-side electrode 410 include Ag finger grids, which can be formed using various techniques, including, but not limited to: screen printing of Ag paste, inkjet or aerosol printing of Ag ink, and evaporation. In some embodiments, front-side electrode 408 and back-side electrode 410 can include a Cu grid formed using various techniques, including, but not limited to: electroless plating, electroplating, sputtering, and evaporation.

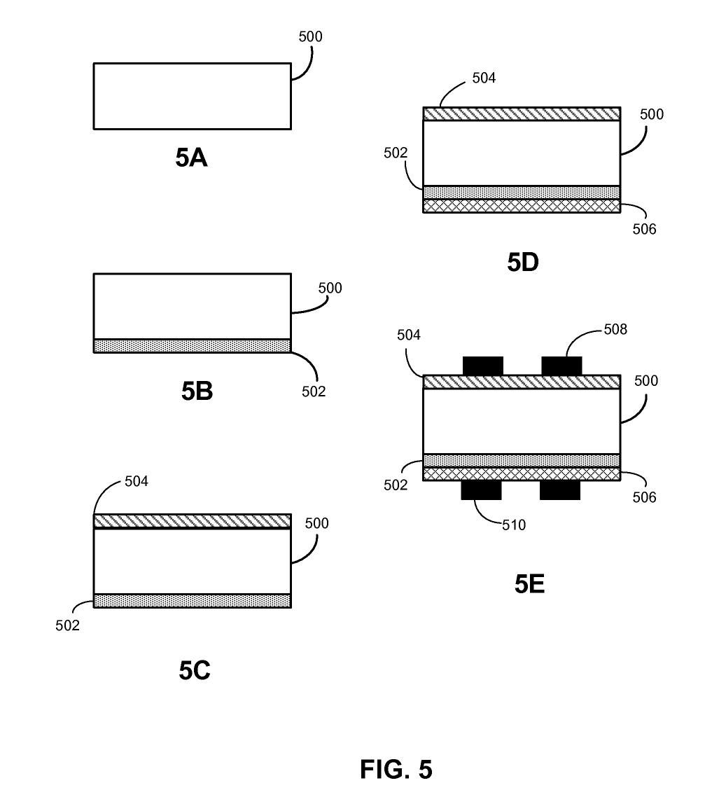

In one embodiment, the TCO/QTB structure can be placed at the backside of the solar cell to act as an electron-collecting BSF layer. FIG. 5 presents a diagram illustrating the process of fabricating a solar cell with a novel electron-collecting BSF layer, in accordance with an embodiment of the present invention.

In operation 5A, an SG-Si substrate 500 is prepared using a process that is similar to operation 4A. In one embodiment, SG-Si substrate 500 is lightly doped with n-type dopants with a doping concentration ranging between 5×10¹⁴/cm³ and 1×10¹⁶/cm³.

In operation 5B, a thin layer of high-quality (with Dᵢₜ less than 1×10¹¹/cm²) dielectric or wide bandgap semiconductor material is deposited on the back surface of SG-Si substrate 500 to form back-side passivation/tunneling layer 502. The processes and materials that can be used to form back-side passivation/tunneling layer 502 are similar to the ones used in operation 4B. In one embodiment, both the front and back surfaces of SG-Si substrate 500 are deposited with a thin layer of dielectric or wide bandgap semiconductor material.

In operation 5C, a layer of a-Si with graded doping is deposited on the front surface of SG-Si substrate 500 to form an emitter layer 504, which faces the incident sunlight. In one embodiment, emitter layer 504 collects hole current and is doped with p-type dopants, such as boron. The thickness of emitter layer 504 is between 2 and 50 nm. Note that the doping profile of emitter layer 504 can be optimized to ensure good ohmic contact, minimum light absorption, and a large built-in electrical field. In one embodiment, the doping concentration of emitter layer 504 varies from 1×10¹²/cm³ to 5×10²⁰/cm³. In a further embodiment, the region within emitter layer 504 that is adjacent to SG-Si substrate 500 has a lower doping concentration, and the region that is away from SG-Si substrate 500 has a higher doping concentration. The lower doping concentration ensures minimum defect density at the interface, and the higher concentration on the other side prevents emitter layer depletion. In addition to a-Si, materials used to form emitter layer 504 can also include hydrogenated a-Si, microcrystalline Si, or a semiconductor material with a wide bandgap. Moreover, emitter layer 504 can include other types of structures, such as MIS or a TCO-insulator-semiconductor structure. Note that, in order to collect holes, the TCO used here needs to have a high (at least 5.0 eV) work function.

In operation 5D, a layer of low work function TCO material is deposited on the surface of passivation/tunneling layer 502 to form a back-side TCO layer 506. Materials and processes that can be used to form back-side TCO layer 506 are similar to the ones used in operation 4C.

The combination of low work function TCO layer 506 and passivation/tunneling layer 502 functions as an electron-collecting BSF layer when directly interfaced with SG-Si substrate 500. In addition to collecting electron current, the TCO/QTB structure also passivates the backside of the solar cell.

In operation 5E, front-side electrode 508 and back-side electrode 510 are formed on the surfaces of emitter layer 504 and TCO layer 506, respectively. Materials and processes that can be used to form front-side electrode 508 and back-side electrode 510 are similar to the ones used in operation 4E.

### Higher Work Function TCO

Note that, if the selected TCO material has a work function that is slightly higher (by about 0.05-0.15 eV) than the c-Si conduction band edge, an additional fabrication operation is needed before the formation of the TCO/QTB structure. The additional fabrication operation includes shallow doping of n-type dopants at the surface of the base layer. In one embodiment, the peak carrier concentration of the shallow doping is at least 1×10¹⁹/cm³ and the doping depth is less than 100 nm. In a further embodiment, the shallow doping process involves one or more of: diffusion of doped silica glass, ion implantation, laser doping, etc. The TCO/QTB structure can then be formed on top of the shallow, heavily n-doped layer.

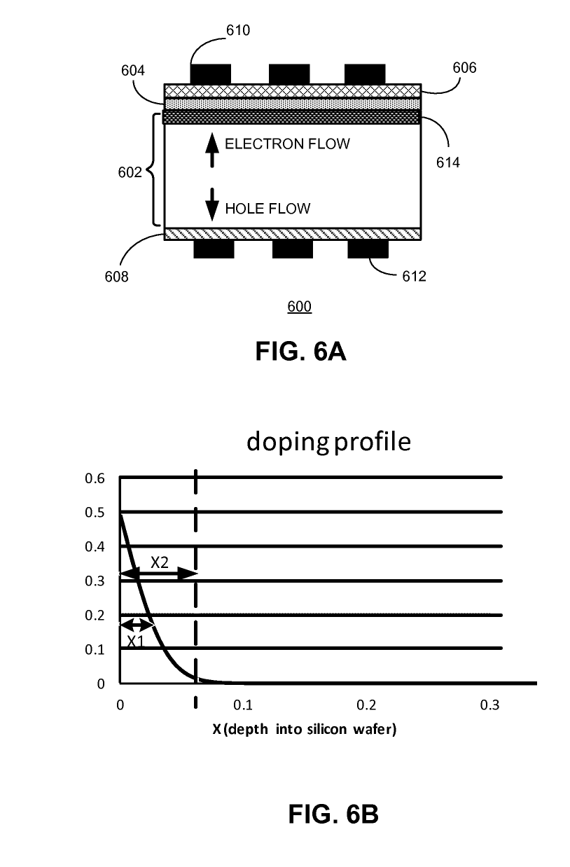

FIG. 6A presents a diagram illustrating an exemplary solar cell with the TCO/QTB electron collector, in accordance with an embodiment of the present invention. Solar cell 600 includes a substrate 602, a QTB layer 604, a TCO layer 606, a BSF layer 608, a front-side electrode 610, and a back-side electrode 612. Solar cell 600 is similar to solar cell 200 shown in FIG. 2, except that in solar cell 600, substrate 602 include a shallow doping region 614 at the interface between substrate 602 and the TCO/QTB structure. In one embodiment, shallow doping region 614 is heavily doped with n-type dopants. In a further embodiment, the peak doping concentration of shallow doping region 614 is at least 1×10¹⁹/cm³. For diffusion doping or implantations, the peak doping concentration often occurs at the surface of substrate 602.

FIG. 6B presents a diagram illustrating an exemplary doping profile of the shallow doping. When surface doping is used, the doping profile is exponential with the surface having a maximum doping concentration. In FIG. 6B, X1 defines the depth into the substrate where the doping concentration drops to 1/e of the peak doping concentration, and X2 defines the depth where the doping concentration drops to the background doping level. X1 is often referred to as junction depth. Note that the numbers shown in FIG. 6B are all relative values. To avoid blue blindness, this additional n-type doping should be shallow enough. In one embodiment, the doping is controlled to have X1 being less than 100 nm, and X2 being less than 300 nm.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

What is claimed is:

1. A method for fabricating a solar cell, comprising:
obtaining a base layer comprising crystalline Si (c-Si);
forming an electron collector on a first side of the base layer, wherein the electron collector includes a quantum-tunneling-barrier (QTB) layer situated adjacent to the base layer and a transparent conducting oxide (TCO) layer situated adjacent to the QTB layer, and wherein the TCO layer has a work function of less than 4.2 eV; and
forming a hole collector on a second side of the base layer, wherein the second side is opposite the first side.

2. The method of claim 1, wherein the base layer comprises at least one of:
a mono-crystalline silicon wafer; and
an epitaxially grown crystalline-Si (c-Si) thin film.

3. The method of claim 1, wherein the QTB layer comprises at least one of:
silicon oxide (SiOₓ);
hydrogenated SiOₓ;
silicon nitride (SiNₓ);
hydrogenated SiNₓ;
aluminum oxide (AlOₓ);
aluminum nitride (AlNₓ);
silicon oxynitride (SiON);
hydrogenated SiON;
amorphous Si (a-Si);
hydrogenated a-Si;
carbon doped Si; and
SiC.

4. The method of claim 1, wherein the QTB layer has a thickness between 1 and 50 angstroms.

5. The method of claim 1, wherein the QTB layer comprises one of: SiOₓ and hydrogenated SiOₓ, and wherein the QTB layer is formed using at least one of the following techniques:
running hot deionized water over the base layer;
ozone oxygen oxidation;
atomic oxygen oxidation;
thermal oxidation;
wet or steam oxidation;
atomic layer deposition;
low-pressure radical oxidation; and
plasma-enhanced chemical-vapor deposition (PECVD).

6. The method of claim 1, wherein the TCO layer includes one or more of: tungsten doped indium oxide (IWO), Sn doped indium oxide (ITO), fluorine doped tin oxide (F:SnO₂), zinc doped indium oxide (IZO), zinc and tungsten doped indium oxide (IZWO), and aluminum doped zinc oxide (AZO).

7. The method of claim 1, wherein the TCO layer is formed using a low damage deposition technique comprising one of:
radio frequency (RF) sputtering;
thermal evaporation;
molecular beam epitaxy (MBE);
metalorganic chemical-vapor deposition (MOCVD);
atomic layer deposition (ALD); and
ion plating deposition (IPD).

8. The method of claim 1, wherein the electron collector is situated on a front surface of the solar cell, facing incident light, and wherein:
if the base layer is lightly doped with p-type dopants, then the electron collector acts as a front-side emitter; and
if the base layer is lightly doped with n-type dopants, then the electron collector acts as a front surface field (FSF) layer.

9. The method of claim 8, wherein the hole collector is situated on a back surface of the solar cell, facing away from the incident light, and wherein:
if the base layer is lightly doped with p-type dopants, then the hole collector acts as a back surface field (BSF) layer; and
if the base layer is lightly doped with n-type dopants, then the hole collector acts as a back-side emitter.

10. The method of claim 8, wherein the hole collector comprises one or more of:
a QTB layer;
amorphous-Si (a-Si);
hydrogenated a-Si; and
microcrystalline Si.

11. The method of claim 8, wherein the hole collector is graded doped and has a doping concentration ranging between 1×10¹²/cm³ and 5×10²⁰/cm³.

12. The method of claim 1, wherein the electron collector is situated on a back surface of the solar cell, facing away from incident light, and wherein:
if the base layer is lightly doped with p-type dopants, then the electron collector acts as a back-side emitter; and
if the base layer is lightly doped with n-type dopants, then the electron collector acts as a back surface field (BSF) layer.

13. The method of claim 12, wherein the hole collector is situated on a front surface of the solar cell, facing the incident light, and wherein:
if the base layer is lightly doped with p-type dopants, then the hole collector acts as a front surface field (FSF) layer; and
if the base layer is lightly doped with n-type dopants, then the hole collector acts as a front-side emitter.

14. The method of claim 1, wherein the base layer has an n-type or a p-type doping concentration ranging between 5×10¹⁴/cm³ and 1×10¹⁶/cm³.

15. The method of claim 1, wherein obtaining the base layer further comprises shallow doping a surface of the base layer with n-type dopants, wherein the shallow doping has a peak doping concentration of at least 1×10¹⁹/cm³, and wherein the shallow doping has a junction depth of less than 100 nm.

16. A solar cell, comprising:
a base layer comprising crystalline Si (c-Si);
an electron collector situated on a first side of the base layer, wherein the electron collector includes a quantum-tunneling-barrier (QTB) layer situated adjacent to the base layer and a transparent conducting oxide (TCO) layer situated adjacent to the QTB layer, and wherein the TCO layer has a work function of less than 4.2 eV; and
a hole collector situated on a second side of the base layer, wherein the second side is opposite the first side.

17. The solar cell of claim 16, wherein the base layer comprises at least one of:
a monocrystalline silicon wafer; and
an epitaxially grown crystalline-Si (c-Si) thin film.

18. The solar cell of claim 16, wherein the QTB layer comprises at least one of:
silicon oxide (SiOₓ);
hydrogenated SiOₓ;
silicon nitride (SiNₓ);
hydrogenated SiNₓ;
aluminum oxide (AlOₓ);
aluminum nitride (AlNₓ);
silicon oxynitride (SiON);
hydrogenated SiON;
amorphous Si (a-Si);
hydrogenated a-Si;
carbon doped Si; and
SiC.

19. The solar cell of claim 16, wherein the QTB layer has a thickness between 1 and 50 angstroms.

20. The solar cell of claim 16, wherein the QTB layer comprises one of: SiOₓ and hydrogenated SiOₓ, and wherein the QTB layer is formed using at least one of the following techniques:
running hot deionized water over the base layer;
ozone oxygen oxidation;
atomic oxygen oxidation;
thermal oxidation;
wet or steam oxidation;
atomic layer deposition;
low-pressure radical oxidation; and
plasma-enhanced chemical-vapor deposition (PECVD).

21. The solar cell of claim 16, wherein the TCO layer includes one or more of: tungsten doped indium oxide (IWO), Sn doped indium oxide (ITO), fluorine doped tin oxide (F:SnO₂), zinc doped indium oxide (IZO), zinc and tungsten doped indium oxide (IZWO), and aluminum doped zinc oxide (AZO).

22. The solar cell of claim 16, wherein the TCO layer is formed using a low damage deposition technique comprising one of:
radio frequency (RF) sputtering;
thermal evaporation;
molecular beam epitaxy (MBE);
metalorganic chemical-vapor deposition (MOCVD);
atomic layer deposition (ALD); and
ion plating deposition (IPD).

23. The solar cell of claim 16, wherein the electron collector is situated on a front surface of the solar cell, facing incident light, and wherein:
if the base layer is lightly doped with p-type dopants, then the electron collector acts as a front-side emitter; and
if the base layer is lightly doped with n-type dopants, then the electron collector acts as a front surface field (FSF) layer.

24. The solar cell of claim 23, wherein the hole collector is situated on a back surface of the solar cell, facing away from the incident light, and wherein:
if the base layer is lightly doped with p-type dopants, then the hole collector acts as a back surface field (BSF) layer; and
if the base layer is lightly doped with n-type dopants, then the hole collector acts as a back-side emitter.

25. The solar cell of claim 23, wherein the hole collector comprises one or more of:
a QTB layer;
amorphous-Si (a-Si);
hydrogenated a-Si; and
microcrystalline Si.

26. The solar cell of claim 23, wherein the hole collector is graded doped and has a doping concentration ranging between 1×10¹²/cm³ and 5×10²⁰/cm³.

27. The solar cell of claim 16, wherein the electron collector is situated on a back surface of the solar cell, facing away from incident light, and wherein:
if the base layer is lightly doped with p-type dopants, then the electron collector acts as a back-side emitter; and
if the base layer is lightly doped with n-type dopants, then the electron collector acts as a back surface field (BSF) layer.

28. The solar cell of claim 27, wherein the hole collector is situated on a front surface of the solar cell, facing the incident light, and wherein:
if the base layer is lightly doped with p-type dopants, then the hole collector acts as a front surface field (FSF) layer; and
if the base layer is lightly doped with n-type dopants, then the hole collector acts as a front-side emitter.

29. The solar cell of claim 16, wherein the base layer has an n-type or a p-type doping concentration ranging between 5×10¹⁴/cm³ and 1×10¹⁶/cm³.

30. The solar cell of claim 16, wherein the base layer further comprises a shallow doping layer heavily doped with n-type dopants, wherein the shallow doping layer has a peak doping concentration of at least 1×10¹⁹/cm³, and wherein the shallow doping layer has a junction depth of less than 100 nm.
